(19) United States
(12) Patent Application Publication
(10) Pub. No.: US 2026/0341353 A1
(43) Pub. Date: Oct. 29, 2026

(54) VOLTAGE-DIVIDER BASED RESISTIVE UNIT CELL

(71) Applicant: International Business Machines Corporation, Armonk, NY (US)

(72) Inventors: Abhairaj Singh, Adliswil (CH); Manuel Le Gallo-Bourdeau, Horgen (CH); Abu Sebastian, Adliswil (CH)

(21) Appl. No.: 19/186,889

(22) Filed: Apr. 23, 2025

(51) Int. Cl. G11C 13/00

(52) U.S. Cl. CPC G11C 13/004; G11C 13/0038

(57) ABSTRACT

A non-volatile memory (NVM) device and method of operating. The device includes a resistive voltage-divider based cell and readout structure to perform fast in-memory computations (IMC). The voltage-divider based cell stores one bit (1b) data in a binary complementary format onto true and complementary selectable non-volatile resistor memory devices configured to form a common internal node. Readout operations are enabled by activating selectors of the memory devices though a select line and developing a voltage division at the internal node by a charge re-distribution between the two selected devices. A gate-controlled device is responsive to the internal node voltage to regulate an output read path based on its conductance and discharge a signal representing the stored bit value. Fast readout occurs by the decoupling of the read path from the high resistive path of resistive device when reading the bit value at a voltage threshold detecting read sensor device.

### FIELD OF THE DISCLOSURE

The present application relates to generally to non-volatile memory systems, e.g., resistive memory and related memory systems employing the same. More particularly, the present application relates to a resistive device unit-cell based on voltage-division and related reading schemes that use charge-sharing techniques to perform robust and fast fully-digital in-memory computation for efficient in-memory computing (IMC) systems and memory systems.

Some computer architectures employ digital in-memory computing (DIMC) or analog in-memory computing (AIMC) devices and/or compute-in-memory (CIM) processing which enable data operations to be performed directly on the data memory, rather than having to be transferred to CPU registers first. Such architectures provide benefits such as improving the power usage and performance of moving data between the processor and the main memory.

Typically, to perform read operations using resistive devices, three methodologies are being utilized: type 1) current readout of one-transistor-one-resistor (1T1R) unit cells and the use of current sense-amplifiers; type 2) voltage readout of the 1T1R unit cells and the use of voltage sense-amplifiers; and type 3) use of voltage-divider based unit cell with constant power ON memory, followed by current readout of the unit cells and the use of current sense-amplifiers. Each of these existing readout schemes involve voltage or current sensing of the resistance value stored in the unit cell. Since this voltage/current value is proportional to the absolute value of the stored resistance value, the latency increases with the stored resistance value in the unit cell to ensure enough margin between the logic 0 and logic 1 states. This results in high read latency.

Since this voltage/current value is proportional to the absolute value of the stored resistance value, the variation in programmed resistance directly impacts the accuracy and efficiency of the system. The sensing margin is reduced (accuracy), and latency and energy consumption are increased to restore the accuracy of the read operation.

Currently, these solutions do not include a memory structure or clear write scheme for the unit cells and suffer from low resistance ratio of the two states. Moreover, all the above suffer from limited speed up, poor accuracy against process, voltage variations and poor power-efficiency by using expensive sense-amplifiers when being deployed in a memory-only unit.

Currently, no solutions involve DIMC-based accumulation while using resistive devices due to poor efficiency and read accuracy.

### SUMMARY

In one aspect of the present disclosure, there is provided a resistive voltage-divider based unit-cell and associated readout schemes for increased efficiency in in-memory computing systems.

Further to this aspect, there is provided an associated resistive voltage-divider based unit-cells unit-cell readout structure and method for an in-memory computing (IMC) unit of an in-memory computing system.

Further to this aspect, the resistive voltage-divider based unit-cells and readout structure provides for a more robust, high-speed and low-power solution for a memory thereby improving efficiency and accuracy, e.g., for computing data-intensive operations such as in-memory matrix-vector-multiplication (MVM) operations.

In one aspect, the resistive voltage-divider based unit-cell structure is a unit cell storing 1b data in a binary complementary format onto true and complementary selectable non-volatile memory devices, a select line, a read line, and a common internal node.

Further to this aspect, the resistive voltage-divider based unit-cell structure is enabled for a readout operation by activating the selectors of the true and complementary memory devices though the select line, developing a voltage-division at an internal node (INT) by allowing charge re-distribution between the two selected devices. In this aspect, the INT node is connected to the gate terminal of a gate-controlled device to regulate a read path based on its conductance, by sinking a read line voltage connected to a first terminal towards ground. A NOR or NAND gate is used to sense the amount of toggling of the read line to determine the (binary) output.

Further to this aspect, the input activation (in an IMC unit) or wordline activation (in a memory-only unit) enables the unit cell.

In a further aspect, for IMC, this input or wordline activation is followed by a distributed ADDER tree to accumulate the partial products digitally, and shift-and-add circuits to account for input bit significance.

In one aspect of the disclosure, there is provided a memory device for in-memory computing operations. The memory device comprises: a resistive unit cell comprising: a first switching device (NL) and a first resistor connected in series; and a second switching device (NR) and a second resistor connected in series, each first switching device and second switching device having a terminal connected at a single common node to form a voltage divider circuit, the voltage divider circuit storing a bit value in a binary complementary format as a floating charge distributed between the first resistor and second resistor, and the first switching device (NL) and second switching device (NR) activated to provide a voltage at the single common node; and a gate-controlled switching transistor device (NG) having a control terminal connected to the single common node for receiving the voltage provided at the single common node, the gate-controlled switching device responsive to the voltage provided at the single common node for generating a read path through the gate-controlled switching transistor device to discharge a signal representing the stored bit value from either the first resistor or second resistor for reading the bit value at a read sensor device.

In this aspect, the resistive voltage-divider based unit cell decouples the read path from the high resistive path of resistive devices and is concerned with the almost full-ON or OFF of gate-controlled switching transistor device (NG) discharge or not-discharging of a read bitline (BL), thereby providing for fast readout for large memory arrays with binary storage.

In another aspect of the present disclosure, there is provided a method for operating a memory device. The method comprises: storing a weight value in a resistive unit cell, the resistive unit cell comprising: a first switching device (NL) and a first resistor connected in series; and a second switching device (NR) and a second resistor connected in series, each first switching device and second switching device having a terminal connected at a single common node to form a voltage divider circuit, the voltage divider circuit storing a bit value in a binary complementary format as a floating charge distributed between the first resistor and second resistor, and the first switching device (NL) and second switching device (NR) activated to provide a voltage at said single common node, and a gate-controlled switching transistor device (NG) having a control terminal connected to said single common node for receiving said voltage provided at said single common node; and generating a read path through the gate-controlled switching transistor device to discharge a signal representing said stored bit value from either said first resistor or second resistor for reading said bit value at a read sensor device.

In yet another aspect of the present application there is provided an in-memory computing system comprising: a plurality of bit line conductors organized as columns of an array; a plurality of wordline conductors organized as rows of the array; an array of resistive unit cells along a respective row, each respective resistive unit cell of the array associated with a respective bit line conductor of a respective column and each resistive unit cell of the array associated a single wordline conductor of a single row for activating each of the resistive unit cells along the row of the array, each resistive unit cell comprising: a first switching device (NL) and a first resistor connected in series; and a second switching device (NR) and a second resistor connected in series, each first switching device and second switching device having a terminal connected at a single common node to form a voltage divider circuit, the voltage divider circuit storing a bit value in a binary complementary format as a floating charge distributed between the first resistor and second resistor, and the first switching device (NL) and second switching device (NR) activated to provide a voltage at the single common node; and a gate-controlled switching transistor device (NG) having a control terminal connected to the single common node for receiving the voltage provided at the single common node, the gate-controlled switching device responsive to the voltage provided at the single common node for generating a read path through the gate-controlled switching transistor device to discharge a signal representing the stored bit value from either the first resistor or second resistor for reading the bit value at a read sensor device associated with the respective bit line conductor of the respective column, wherein each respective read sensor of multiple resistive unit cells along the single row simultaneously read a stored bit value from the respective resistive unit cell of the single row.

In yet another aspect of the present application there is provided a method for performing an in-memory computing operation. The method comprises: storing a weight value in a complementary binary format in multiple resistive unit cells, each the resistive unit cell comprising: a first switching device (NL) and a first resistor connected in series; and a second switching device (NR) and a second resistor connected in series, each first switching device and second switching device having a terminal connected at a single common node to form a voltage divider circuit, the voltage divider circuit storing a bit of the weight value in a binary complementary format as a floating charge distributed between the first resistor and second resistor, and the first switching device (NL) and second switching device (NR) activated to provide a voltage at the single common node; and a gate-controlled switching transistor device (NG) having a control terminal connected to the single common node for receiving the voltage provided at the single common node; and receiving an input operand at a select wordline conductor connected to a gate control terminal of each the first switching device (NL) and second switching device (NR) of each multiple resistive unit cell, the input operand representing a signal to be multiplied by the stored weight value, the input operand activating the first switching device (NL) and the second switching device (NR) of each the multiple resistive unit cell to control a multiplication operation of the stored weight value and the input operand at the multiple resistive unit cells.

In yet another aspect of the present application there is provided a memory device for in-memory computing operations. The memory device comprising: a resistive unit cell comprising: a first switching device (NL) and a first resistor connected in series; and a second switching device (NR) and a second resistor connected in series, each first switching device and second switching device having a terminal connected at a single common node to form a voltage divider circuit, the voltage divider circuit storing a multi-bit value in a binary complementary format as a floating charge distributed between the first resistor and second resistor, and the first switching device (NL) and second switching device (NR) activated to provide a voltage at the single common node; and a gate-controlled switching transistor device (NG) having a control terminal connected to the single common node for receiving the voltage provided at the single common node, the gate-controlled switching device responsive to the voltage provided at the single common node for generating a read path through the gate-controlled switching transistor device to discharge a signal representing the stored multi-bit value from either the first resistor or second resistor for reading the bit value at a read sensor device, the multi-bit value determined based on a conductance ratio of the first resistor and the second resistor.

### BRIEF DESCRIPTION OF THE DRAWINGS

Further features as well as the structure and operation of various embodiments are described in detail below with reference to the accompanying drawings. In the drawings, like reference numbers indicate identical or functionally similar elements.

FIGS. 1A-1B depict various embodiments of a voltage-divider based resistive unit cell according to an aspect of the present disclosure;

FIG. 2 depicts use of a readout circuit for the resistive voltage-divider-based (1b) unit cell or multiple resistive voltage-divider-based (1b) unit cells along an array column according to embodiments of the invention;

FIG. 3A conceptually depicts the current flow through the readout path through gate-controlled device transistor when an input operand is to be multiplied by different stored bit values at the resistive voltage-divider-based unit cell according to an embodiment;

FIG. 3B shows an example timing of the various signals at the resistive voltage-divider-based (1b) unit cell when performing different MVM operations in an in-memory computing system according to an embodiment;

FIG. 4 conceptually depicts a digital in-memory computing system employing pluralities of resistive voltage-divider-based (1b) unit cell(s) for in-memory computing operations according to an aspect of the invention;

FIG. 5 conceptually shows the DIMC system architecture for performing MVM operations, e.g., for AI/neural network model training and prediction applications, according to an aspect of the invention;

FIG. 6 shows an embodiment of the resistive voltage-divider-based (1b) unit cell of FIG. 1B when configured for binary storage, i.e., for storing 1b data in a binary complementary format onto true and complementary NVM resistive devices respectively according to an aspect of the invention;

FIG. 7A shows the resistive voltage-divider-based (1b) unit cell of FIG. 1B employed as a memory cell to store one bit (1b) and FIG. 7B shows multiple resistive voltage-divider-based (1b) unit cells configurable as a memory structure for storing weight matrix array values for DIMC or AIMC operations in an in-memory computing system according to embodiments herein;

FIG. 8 depicts a variation of the resistive voltage-divider-based (1b) unit cell of FIG. 1B to accommodate a PMOS-based transistor device technology and use of NAND gate sensing device. according to embodiments herein;

FIG. 9 depicts a three-dimensional (3D) NAND-flash NVM architecture 900 incorporating the resistive voltage-divider-based unit cell structure of FIG. 1B;

FIG. 10 depicts a three-dimensional (3D) NOR-flash NVM architecture 1000 incorporating the resistive voltage-divider-based unit cell structure of FIG. 1B;

FIG. 11 depicts a further result of a voltage-divider-based NVM device configured for multi-level storage and readout, for example, according to the embodiments herein; and

FIG. 12 depicts a further embodiment having a DIMC computing block 1200 using 2D non-volatile memory 1205.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

In an aspect of the present disclosure, there is provided a resistive non-volatile memory (NVM) and specifically a resistive voltage-divider based unit cell to perform robust and fast fully digital in-memory computation (IMC).

According to a further aspect of the present invention, there is provided a resistive voltage-divider-based unit cell and unit-cell readout structure and method. The resistive voltage-divider based unit cell can store one bit (1b) data in a binary complementary format onto true and complementary selectable non-volatile memory devices, a select word line, a read bit line, and a common internal node.

The resistive voltage-divider-based unit cell is enabled for a readout operation by activating selectors of the true and complementary devices though the select line, developing a voltage division at an internal node (INT) by allowing charge re-distribution between the two selected devices. The INT node is connected to a GATE terminal of a gate-controlled device (TR_{INT}). The gate-controlled device (TR_{INT}) regulates a read path based on its conductance, by sinking a read line voltage connected to a first terminal towards ground.

In an aspect, there is provided a memory device for in-memory computing operations. The memory device comprises a resistive unit cell comprising: a first switching device (NL) and a first resistor connected in series; and a second switching device (NR) and a second resistor connected in series, each first switching device and second switching device having a terminal connected at a single common node to form a voltage divider circuit, the voltage divider circuit storing a bit value in a binary complementary format as a floating charge distributed between the first resistor and second resistor, and the first switching device (NL) and second switching device (NR) activated to provide a voltage at the single common node; and a gate-controlled switching transistor device (NG) having a control terminal connected to the single common node for receiving the voltage provided at the single common node, the gate-controlled switching device responsive to the voltage provided at the single common node for generating a read path through the gate-controlled switching transistor device to discharge a signal representing the stored bit value from either the first resistor or second resistor for reading the bit value at a read sensor device.

Advantageously, the resistive voltage-divider based unit cell decouples the read path from the high resistive path of resistive devices and is concerned with the almost full-ON or OFF of gate-controlled switching transistor device (NG) discharge or not-discharging of a read bitline (BL), thereby providing for fast readout for large memory arrays with binary storage.

The readout circuit of a one bit (1b) or multi-bit value is robust against device variations and provides a binary output. Further, the readout circuit does not use an expensive sense-amplifier; but rather uses a simple voltage sensor element, e.g., a NOR/NAND gate (as a threshold detector) to sense the difference between a read 0 case and a read 1 case.

Further, the voltage-divider based resistor unit cell is energy efficient in the sense that charge-sharing (between the read bit line BL and gate node of the gate-controlled switching transistor device (NG)) is used in the first phase of the read operation i.e., voltage division.

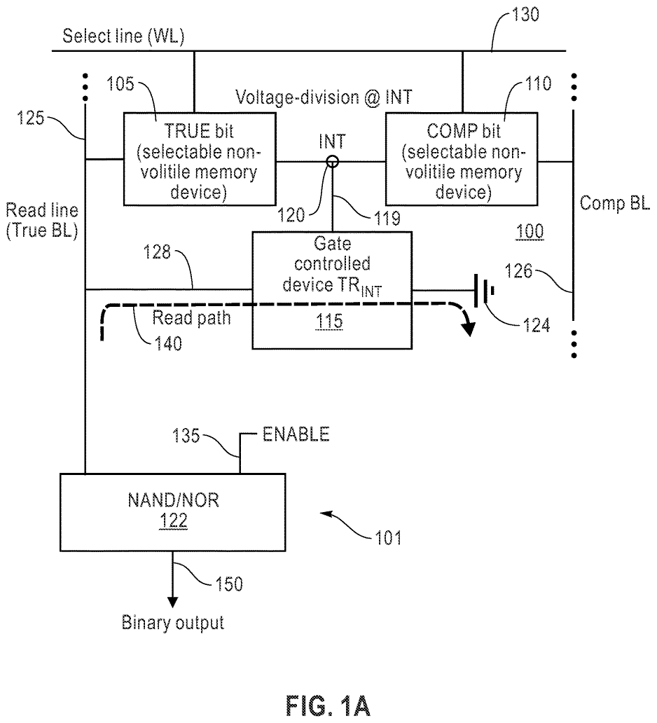

FIG. 1A shows a resistive voltage-divider-based unit cell 100 including a readout structure. The resistive voltage-divider-based unit cell 100 is configured for storing one data bit (1b) in a binary complementary format onto selectable true and complementary resistive devices. The resistive voltage-divider-based unit cell 100 can also be configured to store a weight value for use in in-memory computing operations such as multiply accumulate (MAC) operations and matrix-vector-multiplication (MVM) operations involving matrices and vectors. The resistive voltage-divider-based unit cell 100 has a first selectable non-volatile memory device 105 and a second non-volatile memory device 110 that are connected. First selectable non-volatile memory device 105 includes a first resistive device (e.g., a programmable resistor) and the second selectable non-volatile memory device 110 includes a second resistive device (e.g., a programmable resistor) that each have one end connected at an internal node, i.e., INT node 120, to form a voltage divider circuit. In an embodiment, the first resistive device of the first selectable non-volatile memory device 105 is in an ON state and programmed for storing a weight value (a resistance) while the second resistive device of the second selectable non-volatile memory device 110 is in a complementary state, e.g., an OFF state. In an embodiment, the second resistive device of the second selectable non-volatile memory device 110 is in an ON state and programmed for storing a weight value (a resistance) while the first resistive device of the first selectable non-volatile memory device 105 is in a complementary state, e.g., in an OFF state. Connected to the INT node 120 via conductor 119 of the resistive voltage-divider-based unit cell 100 is a gate-controlled device TR_{INT} 115. Connected to each first and second selectable non-volatile memory (NVM) devices 105, 110 is a common single select wordline (WL) conductor 130 for providing a signal to select a particular NVM device 105, 110. Further, connected to the first selectable non-volatile memory (NVM) device 105 is a read bit line conductor 125, (alternatively referred to as TRUE bitline or TRUE BL 125), for reading an output value to be evaluated as a binary bit value, and connected to the second selectable NVM device 110 is an output read line conductor 126 (alternately referred to as COMP bitline or COMP BL 126), for reading a complementary output value to be evaluated as a binary bit value.

This resistive voltage-divider-based unit cell 100 is enabled for a readout operation, developing a voltage-division at the internal node (INT node 120) between the two resistive devices storing complementary data. This INT node 120 settles at a voltage value independent of the absolute resistance values and only settles as a function of their relative values.

In an output value readout scheme, a GATE of a gate-controlled device TR_{INT} 115 is connected to the INT node 120. The gate-controlled device TR_{INT} 115 regulates a bit value read path 140 based on its conductance i.e., f(V_{INT}), where V_{INT} is a voltage value at the INT node 120. This read path 140 traverses an output conductor 128 connecting the read bit line conductor 125 through the activated gate-controlled device TR_{INT} 115 to a ground potential 124. This read path 140 is decoupled from the resistive devices storing the weight data. The gate-controlled device TR_{INT} 115 regulates the read path 140 based on its conductance, by sinking the bit read line (TRUE BL) voltage connected to the gate-controlled device TR_{INT} 115 towards ground 124.

As shown in FIG. 1A, forming a bit readout structure 101 is a voltage threshold detector device, e.g., in the form of a NOR/NAND gate 122 that is further connected to the read bit line conductor (e.g., TRUE BL) 125. Alternatively, a similar bit readout structure can be connected to the complementary bit line (e.g., COMP BL) 126. The NOR/NAND gate 122 is configured as a voltage threshold detector when enabled to sense the amount of toggling of the voltage discharged at the read bit line conductor 125 to determine the (binary) output 150, e.g., a logic 1 bit or logic 0 bit. In an embodiment, the toggling of the BL implies the discharge of BL during a read operation. The sensing NAND or a NOR gate can typically act as a simple threshold detector, where in case of a low resistance at the first selectable NVM device 105 and high resistance at the second selectable NVM device 110, the read bitline (True BL) discharges below a certain threshold value (e.g., VDD/2), and the NOR/NAND gate 122 output will detect this and switch its output from (1→0). In the other case, the NOR/NAND gate 122 will not switch and will remain at 1.

FIG. 1B shows a more detailed embodiment of the resistive voltage-divider-based unit cell 100 of FIG. 1A. In the resistive voltage-divider-based unit cell structure of FIG. 1B, the first selectable non-volatile memory device 105 includes a transistor device 106, e.g., an n-Type Metal Oxide Semiconductor (NMOS) field effect transistor (FET) (or “NL” transistor device) 106. The NL transistor 106 can be a single NMOS FET transistor or a multi-transistor SRAM device (e.g., 6T, 8T, etc.) and includes a control terminal, i.e., a gate terminal, connecting to the WL conductor 130. Coupled to the drain or source terminal of NL transistor device 106 is first programmable resistor device MEML 107 that is connected at another end to the TRUE read bit line conductor 125. Similarly, the second selectable non-volatile memory device 110 includes a transistor device 111, e.g., an NMOS field effect transistor (or “NR” transistor device) 111. The NR transistor 111 can be a single NMOS FET transistor or a multi-transistor SRAM device (e.g., 6T, 8T, etc.) and includes a control terminal, i.e., a gate terminal, connecting to the WL conductor 130. Coupled to the drain or source terminal of NR transistor device 111 is second programmable resistor device MEMR 112 that is connected at another end to the COMP bitline 126. It should be understood that, in other embodiments, the NL transistor device 106 and the NR transistor device 111 can be a single or multiple PMOS device(s). Each resistor device MEML 107 and MEMR 112 can be a non-volatile memory (NVM) device that stores data as resistance values, e.g., a Resistive Ram (RRAM), a phase change memory (PCM), Ferroelectric RAM (FeRAM), Silicon Storage Technologies (STT)-MRAM, and are programmed with a resistance representing a particular weight value for a multiplication (in-memory computing) operation.

Further, in the resistive voltage-divider-based unit cell 100 of FIG. 1B, the gate controlled device TR_{INT} 115 of FIG. 1A is embodied by further NMOS FET transistor device 116 or “NG” transistor device 116 having a gate terminal directly connected to the INT node 120 and one terminal (drain or source) connected to ground potential 124, and the other terminal (source or drain) connected to the TRUE read bit line conductor 125 through output conductor 128. Further, the gate-controlled device TR_{INT} 115 includes a further NMOS FET transistor device 117 having a gate terminal connecting to a read or write enable conductor line 145 for receiving a read or write operation enable command signal (e.g., WEN or NSEL signal) when conducting read and/or write operations. The drain (or source) terminal of NMOS FET transistor device 117 is connected to the INT node 120 via a conductive line 129 for conducing the V_{INT} to ground potential responsive to an enable signal applied to read or write enable conductor line 145. It should be understood that, in other embodiments, the NG transistor device 116 and the NMOS FET transistor device 117 can be a single or multiple PMOS device(s). When using PMOS technology, the drain or source terminal can be connected to a voltage supply source, e.g., VDD (not shown).

In embodiments, multiple resistive voltage-divider-based unit cells 100 each for storing one data bit (1b) in a binary complementary format onto selectable true (MEML) and complementary (MEMR) resistive devices, can be connected along multiple columns and/or rows to form a multi-bit or multi-byte in-memory storage structure, e.g., for storing a memory vector, memory array or a matrix configuration (not shown) such as for conducting matrix-vector multiplication (MVM) operations in a DIMC or AIMC system.

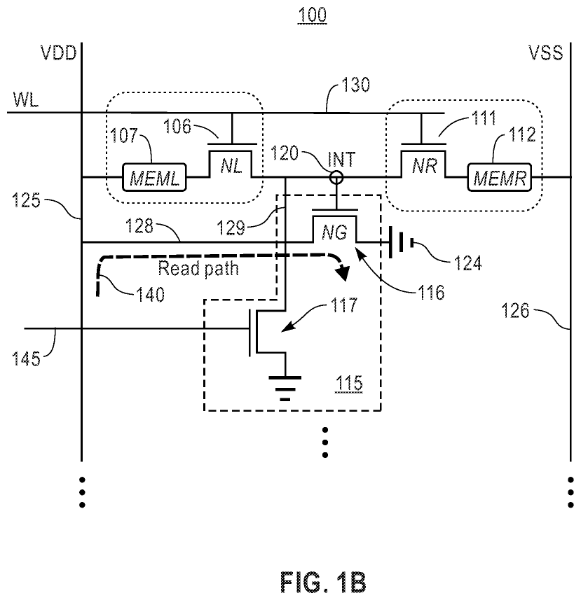

FIG. 2 depicts use of a readout circuit 101 for the resistive voltage-divider-based (1b) unit cell 100 or multiple resistive voltage-divider-based (1b) unit cells 100, e.g., along an array column, each cell for storing one data bit(s) (1b) of a weight value in a binary complementary format on the selectable resistor, MEML, and complementary resistor, MEMR, to ensure fast and reliable readouts. When implemented in a digital or analog in-memory computing system that performs multi-bit IN and multi-bit W based MVM operations, a weight “W” data value is stored as a bit in the programmable TRUE bit and COMP bit resistive devices. In embodiments, as shown in FIG. 2, the resistive voltage-divider-based unit cell 100 exhibits a capacitance such as a global access line capacitance including a capacitance “CT” 202 at the TRUE read bit line conductor 125, a capacitance “CC” 206 at the COMP bitline 126, and a capacitance C_{INT} 204 at the INT node 120. The 1 bit readout scheme is first initialized at the resistive unit cell by assuming that CT≈CC and that the capacitance of global access lines)>> capacitance at the INT node 120, i.e., CT≈CC>>C_{INT}. In embodiments, the CC or CT can be greater than 100× or 200× the capacitance value of C_{INT}.

For the initialization, the read bit line (TRUE) capacitance of CT is initialized to a first (high) rail voltage, e.g., VDD (floating), e.g., by pre-charging the read bit line conductor 125 by connecting it to a VDD voltage supply and then disconnecting it. The read bit line (COMP) capacitance CC is initialized to second (low) rail voltage, e.g., ground or VSS (floating), e.g., by connecting the COMP bit line 126 to a ground potential and then disconnecting it. As the gate-controlled device TR_{INT} 115 is initially off, the capacitance of C_{INT} is also left floating prior to a read operation. After the initialization, when the gate-controlled device TR_{INT} 115 is activated (turned ON), the “ON” resistance of TR_{INT}<<the two resistive device resistances MEML (e.g., TRUE bit resistive element) and MEMR (e.g., COMP bit resistive element). Referring to FIG. 1B, the NG transistor 116 is activated for a resistance ratio dependent and absolute value independent one bit (1b) readout.

In view of FIG. 2, to activate the resistive voltage-divider-based (1b) unit cell 100 using the resistive divider network between TRUE and COMP resistive devices, the WL conductor 130 is enabled to receive an input “IN” voltage signal 210 representing a bit of an operand to be processed in an MVM operation, e.g., IN=1 or 0. Here, the TRUE bitline voltage=VDD (floating) and the COMP bitline voltage=0 (floating). IN activation enables the unit cell allowing charge re-distribution 212, 216 respectively between the respective capacitances CT and CC and C_{INT} depending on respective relative resistive device (i.e., MEML, MEMR) conductance values. The capacitance C_{INT} 204 settles closer to CT voltage (if conductance of TRUE resistive device (resistor device MEML 107) is greater than COMP resistive device (resistor device MEMR 112), or alternatively settles closer to CC voltage (if conductance of COMP resistive device (MEMR) is more than TRUE resistive device (MEML). The INT node 120 settles at a voltage value independent of the absolute resistance values and only settles as a function of their relative values. As the INT node 120 is connected to the gate terminal of the gate-controlled device TR_{INT} 115 (i.e., gate-controlled transistor NG 116 as shown in FIG. 1B) that regulates the read path 140 based on its conductance i.e., f(V_{INT}), this read path 140 is decoupled from the resistive devices storing the data. The settled voltage at the INT node 120, i.e., V_{INT} regulates TR_{INT} i.e., the discharge speed of TRUE BL read bit line conductor 125 towards ground. This true BL voltage signal is sunk to ground in the read path 140 and is sensed by the NAND/NOR gate 122 when enabled using an ENABLE signal 135 to generate binary output. The NOR/NAND gate 122 is a threshold detector that senses the amount of toggling of the read bit line conductor 125 to determine the (binary) output 150.

Referring back to FIG. 1B, the resistive voltage-divider-based unit cell 100 is thus enabled for a readout operation by activating the selectors of the true and complementary devices though the WL conductor 130 functioning as a select line, thereby developing a voltage-division at an internal node (INT) between the two selected devices MEML, MEMR. The INT node 120 is connected to the GATE of the gate-controlled device NG 116. The INT node 120 develops a high ΔV_{INT} (>>voltage threshold of gate-controlled device transistor 116) enabling gate-controlled device transistor 116 (NG) when a multiply operation MULT results in 1 (IN=W=1) or a low ΔV_{INT} (<<voltage threshold of gate-controlled device transistor 116) disabling gate-controlled device transistor 116 (NG) otherwise, e.g., when a multiply operation MULT results in 0 (IN or W=0. An enabled gate-controlled device transistor 116 (NG) toggles the readout line or read path 140 quickly and a disabled gate-controlled device transistor 116 (NG) toggles the readout line or read path 140 slowly. That is, as shown in FIG. 1B, the gate-controlled device TR_{INT} 115 regulates a read path based on its conductance, by sinking a read line voltage connected to a first (e.g., NMOS source or drain) terminal towards the ground.

Thus, based on the charge sharing at INT node 120 which activates gate-controlled device transistor 116 (NG), the NOR/NAND gate 122 can read a logic 0 value at TRUE read bit line conductor 125 when the following condition is met:
Read0: R(TRUE)>R(COMP) or R(MEML)>R(MEMR) and V_{INT}≈low; or alternatively, can read a logic 1 value at TRUE read bit line conductor 125 when the following condition is met:
Read1: R(TRUE)<R(COMP) or R(MEML)<R(MEMR) and V_{INT}≈high.
The NOR/NAND gate 122 senses the amount of toggling of the read bit line conductor 125 to determine the (binary) output.

The readout structure for the resistive voltage-divider-based (1b) unit cell(s) 100 provides for a fast readout: i.e., the TRUE BL read path 140 has no (highly resistive) resistive element, and local C_{INT} node (low loading) toggles during read, thus, fast readout. The voltage divider reacts independent of the absolute resistance value (i.e., is only dependent on the resistance ratio). Hence, resistive element resistance value can be chosen such that a low programming I/V is required, which can lead to more compact unit cells and improved density.

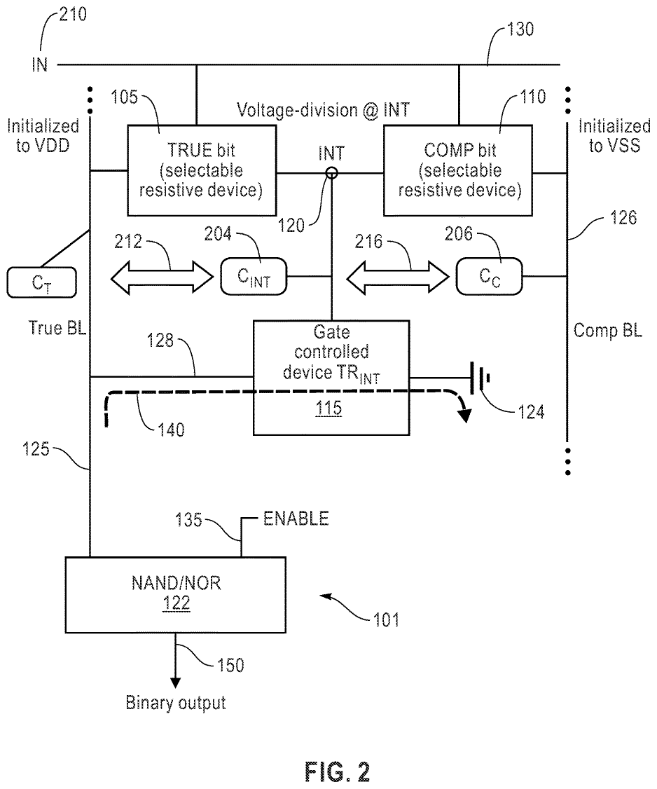

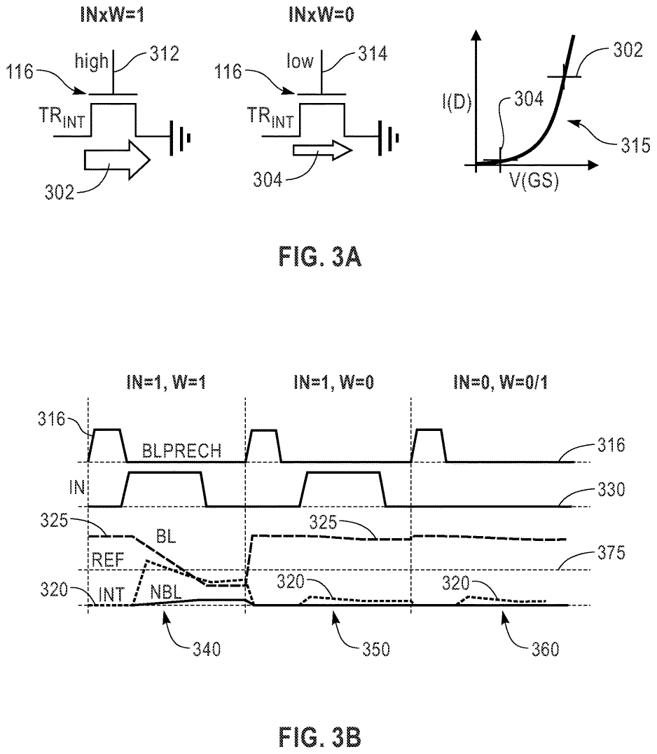

FIG. 3A conceptually depicts the current flow 302 through the read path 140—which corresponds to the source to drain path through gate-controlled device transistor 116 (NG) when an input operand (“IN”) is to be multiplied by a stored bit value of weight stored at the resistive voltage-divider-based unit cell 100. For an example case, one bit of the multi-bit weight (“W”) stored at the resistive unit cell is a logic 1. In an example in-memory computing operation, Operation IN×W=1 results in placing a high V_{INT} voltage 312 at INT node 120 which activates gate-controlled transistor 116 to result in a greater I_{DS} current flow 302 through the gate-controlled device transistor 116. In contrast, for an example case, one bit of the multi-bit weight (“W”) stored at the resistive unit cell is a logic 0. Thus, in an example in-memory computing operation, IN×W=0 results in placing a lower V_{INT} voltage 314 at INT node 120 which activates gate-controlled transistor 116 to result in a lower I_{DS} current flow 304 through the gate-controlled device transistor 116 as shown in in the corresponding I-V curve 315 of FIG. 3A.

FIG. 3B shows an example timing of the various signals at the resistive voltage-divider-based (1b) unit cell 100 when performing different MVM or multiply-accumulate (MAC) operations in an in-memory computing system. For example, during processing of an IN×W MVM operation 340, there is shown an initial pre-charging signal 316 (BLPRECH) applied to the read bit line conductor 125 during processing of MVM operation 340 to render the read bit line conductor 125 with an elevated voltage (W=1) thus having charge stored at the read bit line capacitance. In embodiment, the BLPRECH signal 316 is always enabled before the read operation starts (irrespective of the IN or W conditions). Therefor, true BL is always charged (e.g., to VDD) and complementary BL (NBL) is always discharged before the start of the read/MVM operation. For the MVM operation 340 corresponding to an IN×W operation when IN=1, W=1, the operand IN bit signal 330 on wordline conductor 130 is input for multiplication with the corresponding weight bit value stored in the MEML (or MEMR) memory devices at the resistive voltage-divider-based unit cell 100. As the gate-controlled transistor (NG) 116 is activated in this scenario, the read path 140 sinks current from the read bit line conductor 125. For IN×W operation 340 corresponding to when IN=1, W=1, FIG. 3B shows during the input of the IN signal 330, the V_{INT} voltage level 320 at the INT node 120 increases and the corresponding TRUE BL signal 325 at TRUE read bit line conductor 125 is shown discharging (decreasing) from a peak value over time to below a reference level 375 prior to the next pre-charging signal 316. In this example scenario 340, due to this toggling of the TRUE BL signal 325 from high to low at bit read line conductor 125 that dips below the reference level 375 at the connected detector (NOR/NAND gate), the readout at the connected NOR/NAND gate will provide a corresponding binary output signal of logic 1.

Contrarily, FIG. 3B shows the MVM operation 350 corresponding to an IN×W operation when IN=1, W=0. For IN×W operation 350 corresponding to when IN=1, W=0, after pre-charging the read bit line with pre-charging signal 316, there is shown the increased capacitive charge storage as increased voltage of TRUE BL signal 325 at read bit line conductor 125. However, since the W=0 (e.g., MEML is a high resistance state), in response to input operand signal 330 (IN=1) multiplied by the corresponding weight bit value stored in the MEML memory device at the resistive voltage-divider-based unit cell 100, the gate-controlled transistor (NG) 116 is not activated as the level of V_{INT} voltage level 320 increase at the INT node 120 is negligible due to W=0. As a result, the level of current sunk in the read path 140 from the pre-charged read bit line is negligible. FIG. 3B shows virtually no toggling of the voltage at read bit line conductor 125. As the read bit line voltage of TRUE BL signal 325 does not dip below voltage detector threshold (reference level 375), the corresponding binary output would remain the same. Similarly, FIG. 3B shows the MVM operation 360 corresponding to an IN×W operation when IN=0 and W=0 or W=1. For IN ×W operation 360 corresponding to when IN=0 and either W=0 or W=1, after pre-charging the read bit line with pre-charging signal 316 (e.g., to VDD), there is shown the slight increase capacitive charge storage as TRUE BL signal 325 at read bit line conductor 125. However, since the IN=0, in response to input signal 330 (IN=0) the gate-controlled transistor (NG) 116 is not activated as the level of V_{INT} voltage level 320 at the INT node 120 is negligible. As a result, there is no current sunk in the read path 140 from the pre-charged read bit line and FIG. 3B shows virtually no toggling of the voltage at read bit line conductor 125. As the read bit line voltage, i.e., TRUE BL signal 325, does not dip below voltage detector threshold (reference level 375), the corresponding binary output would remain the same.

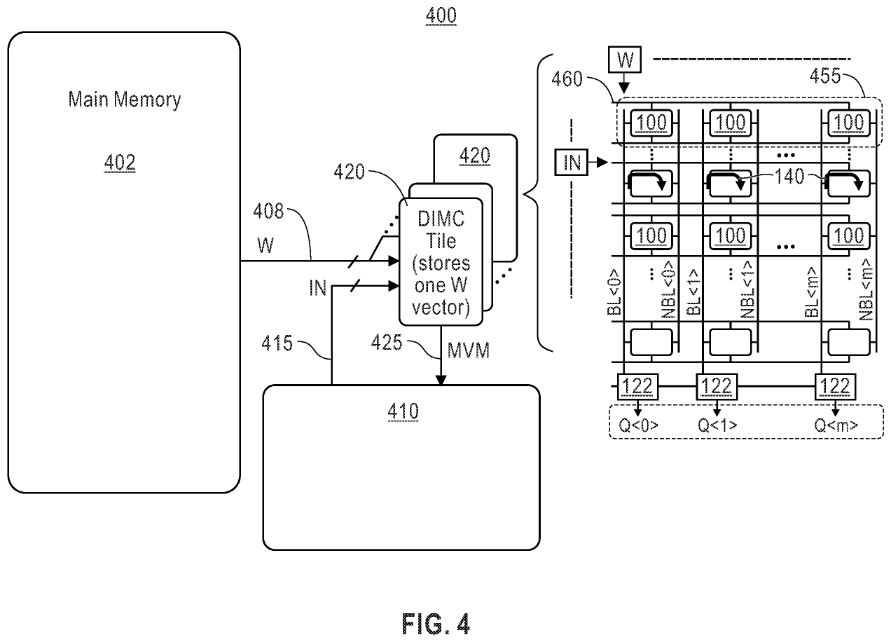

FIG. 4 conceptually depicts a digital in-memory computing system 400 employing pluralities of resistive voltage-divider-based (1b) unit cell(s) 100 for in-memory computing operations. As shown in FIG. 4, DIMC system 400 includes a main memory 402 in which is stored weight bits W such as W matrix data in close proximity to DIMC tile components 420 for fast communication therebetween. The processing at the main memory 402 is as fast as the processing at the DIMC tile component 420 which can be on the order of sub-ns corresponding to the sub-ns readout latency to balance the pipeline of writing of W bits of a vector, i.e., “W” bit inputs 408, to respective DIMC tile components 420 and balance the performing of MVM operations at each DIMC tile component 420. In an embodiment, there are ‘n’ DIMC tile components 420 for storing ‘n’ W vectors. The main memory 402 has a large W (weight) vector storage capacity and can avoid having to include connection(s) to another external or off-chip communication. The storage in the main memory 402 may include main memory tiles (not shown) including SRAM (PMOS and NMOS) devices for storing W (weight) matrix data or it can include other types of memory (e.g., DRAM for low memory requirements, embedded non-volatile memories for large memory requirements).

As shown in FIG. 4, MVM input processing block 410 receives MVM output result bits 425 of the preceding layer/MVM operation result and translates that value to INPUT “IN” input signals 415 as input multiplication operands (multiplicands) to the DIMC tile component 420 for performing the next layer/succeeding MVM operation. In an embodiment, both INs and Ws can be shuffled for each MVM operation. Further, an MVM operation can be simultaneously performed on one row while programming the Ws onto another row. Thus, each MVM operation performed at input processing block 410 can include the following: an MVM read operation in the DIMC tile component 420; a Write operation of the DIMC tile component 420; a read operation in a main memory tile; and requires data communication between the main memory 402 and the DIMC tile component 420.

As shown in FIG. 4, DIMC tile components 420 are implemented to carry out the MVM processing operations when training or using neural network models. As known, a deep neural network (DNN) workload consists of a sequence of layers. The operations in can be performed as a combination of a number of nested for loops, e.g., which iterate over the indices of an input feature map tensor IN, a weight tensor W and that generate an output tensor Q. The tensor operations are performed in a sequence of matrix-vector multiplications (MVM), e.g., by tiling the suitable loops. When performing MVM operations, there is performed a spatial unrolling of the dimensions of the W weight matrix, e.g., to maximize spatial reuse of the activations along the columns of the memory, and accumulation of the partial sums along the rows of the IMC array, as shown as processing 450 depicting the DIMC architecture embodied by the memory 402, input processing block 410 and DIMC tile components 420 in the system of FIG. 4. The nested loops can be sequentially or in-parallel executed for (nested) iterations.

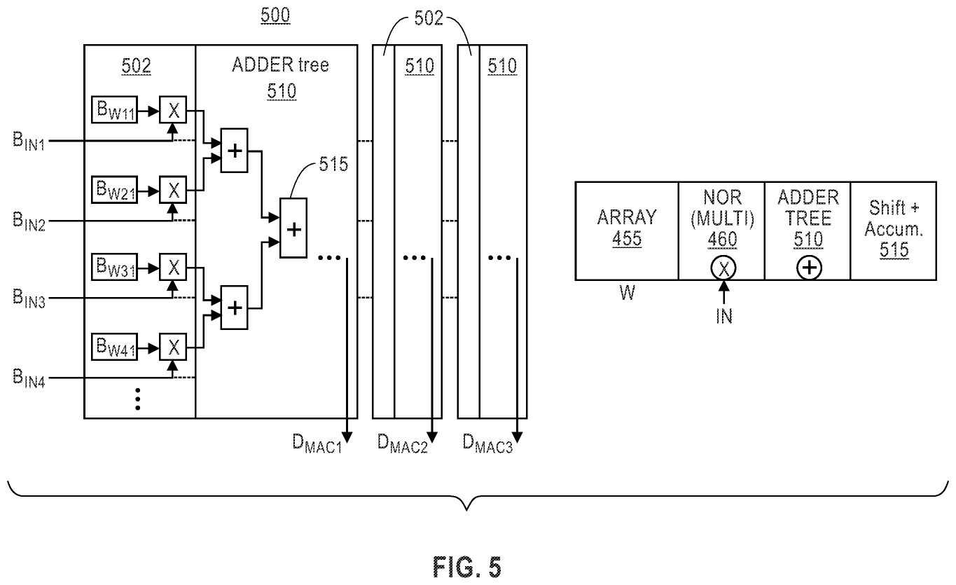

FIG. 5 conceptually shows the DIMC system architecture 500 for performing MVM operations, e.g., for AI/neural network model training and prediction applications. In FIG. 5, the digital in-memory computing (DIMC) tile can perform multi-bit IN and multi-bit W based MVM operations 502 in a fully digital SA-less readout operation, followed by ADDER tree 510 and shift-and-add blocks 515. In such DIMC implementations, at the resistive voltage-divider based unit cells 100 as shown in FIG. 4, for MVM operations performed in DIMC tiles, the weight values of an array matrix W that are stored in one selected row 455 are read out and directly combined with an input bit vector 460 for digital multiplication. Referring back to FIG. 5, multiplication results are further accumulated in the digital domain with an adder tree. Each DIMC array performs fast sub-ns readout of a row i.e., one W (weight) vector, followed by ADDER tree. For a multi-bit W: Multiple columns can be read simultaneously, and multi-bit IN: multiple cycles accommodate IN bits (1b/cycle) and one additional cycle is implemented for shift and add blocks 515. Each “array” 455 can perform one vector-vector multiplication (VVM). For example, 256 such arrays perform 256×256 MVM operations. In an embodiment, there is performed digital inside bitcell in-memory computing, e.g., (1-bit) W readout and NOR (per bitcell) sensing. In other embodiments herein, there is performed analog inside bitcell in-memory computing operation: e.g., bitwise IN×W operations with NOR-based sensing. In an example, there can be input multiple bits of a multi-bit vector for multiplying to a stored bit value in a time multiplex manner. The resistive voltage-divider-based unit cell multiplies a respective input bit of the multi-bit vector to the bit value stored at said resistive unit cell and adds and accumulates the results of each multiplying of a respective input bit of the multi-bit vector to the bit value stored at the resistive unit cell.

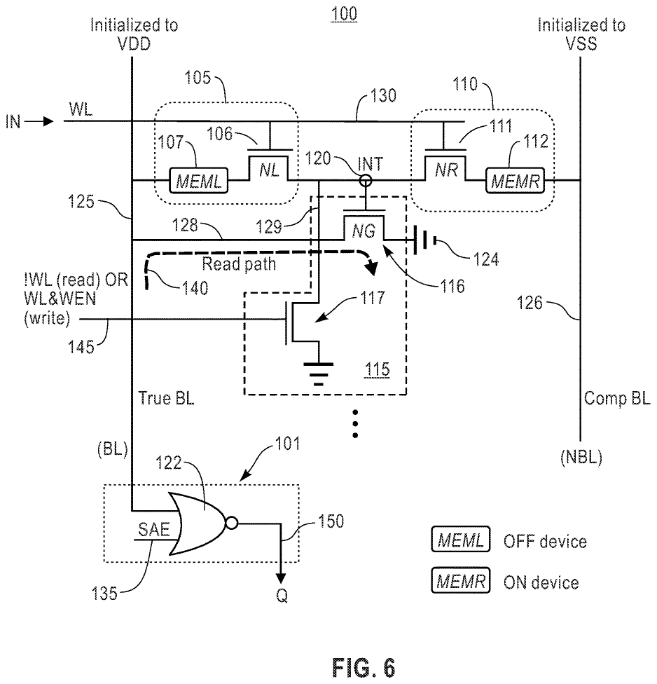

FIG. 6 shows an embodiment of the resistive voltage-divider-based (1b) unit cell 100 of FIG. 1B when configured for binary storage, i.e., for storing 1b data in a binary complementary format onto true and complementary NVM resistive devices, i.e., data stored in MEML (e.g., TRUE) and MEMR (e.g., COMP) resistor devices 107, 112, respectively. The presence of COMP resistive device structure ensures a fast, reliable read operation. In an embodiment, as shown, MEML resistor device 107 is OFF (little or no conducting) and MEMR resistor device 112 is on (conducting). The gate-controlled (NG) transistor 116 is for readout while the NMOS FET transistor device 117 is used for write operation (i.e., separate write operations to each resistive device). The resistive voltage-divider-based (1b) unit cell 100 provides a conductance ratio=cond(TRUE)/cond(COMP).

For a write operation, e.g., for writing W vector bit values into a corresponding DIMC tile of FIG. 4, the two resistive devices MEML and MEMR can be written separately. Writing to the MEML resistor device 107 entails: applying a pre-voltage to TRUE BL read bit line conductor 125 at a value TRUE BL=V_{WRITE}; applying a 0.0 V voltage value or ground at COMP BL 126, i.e., COMP BL=0 (or alternately NBL=0); applying a write enable voltage, e.g., a WEN signal to a value WEN=1, at read or write enable conductor line 145; and applying a wordline voltage signal at wordline conductor 130 at a value corresponding to WL=1. In this MEML writing scenario, the MEML write value path is:
BL→MEML−NL−NS→GND.

Writing to the MEMR resistor device 112 of the corresponding DIMC tile of FIG. 6 entails: applying a voltage to COMP BL 126 at a value COMP BL=V_{WRITE}; applying a 0.0 V voltage value at TRUE BL read bit line conductor 125, i.e., TRUE BL=0 or alternately BL=0; applying a write enable voltage, e.g., a WEN signal at a value WEN=1 at read or write enable conductor line 145; and applying a wordline voltage signal at wordline conductor 130 at a value corresponding to WL=1. In this scenario, the MEMR write value path is:
NBL→MEMR−NR−NS→GND. Both MEML and MEMR can be written simultaneously as well.

For a read operation, e.g., when reading a IN×W vector multiplication result from the in-memory computing operation at the corresponding DIMC tile, using the resistive voltage-divider-based (1b) unit cell 100, the divider is between: MEML+NL and MEMR+NR and includes applying a voltage signal at wordline conductor 130 at a value corresponding to WL=1, applying a VDD (high V) voltage value at TRUE BL read bit line conductor 125, i.e., TRUE BL=VDD or alternately BL=VDD (floating); applying a voltage to COMP BL 126 at a value COMP BL=0 or the NBL=0 (floating). This results in charge sharing at the INT node 120 which activates NG transistor 116. Thus, to read a logic ‘0’:
Read0: R(MEML)>R(MEMR). INT node≈low; and to read a logic ‘1’at output TRUE BL read bit line conductor 125:
Read1: R(MEML)<R(MEMR). INT node≈high. As shown in FIG. 6, the NOR/NAND gate 122 receives voltage detection threshold device ENABLE signal 135 to enable performing NOR-based sensing at the NOR/NAND gate 122 that replaces a sense amplifier. This readout scheme is applicable to all emerging non-volatile memories (NVMs) that store data as resistance values, e.g., RRAM, PCM, FeRAM, STT-MRAM.

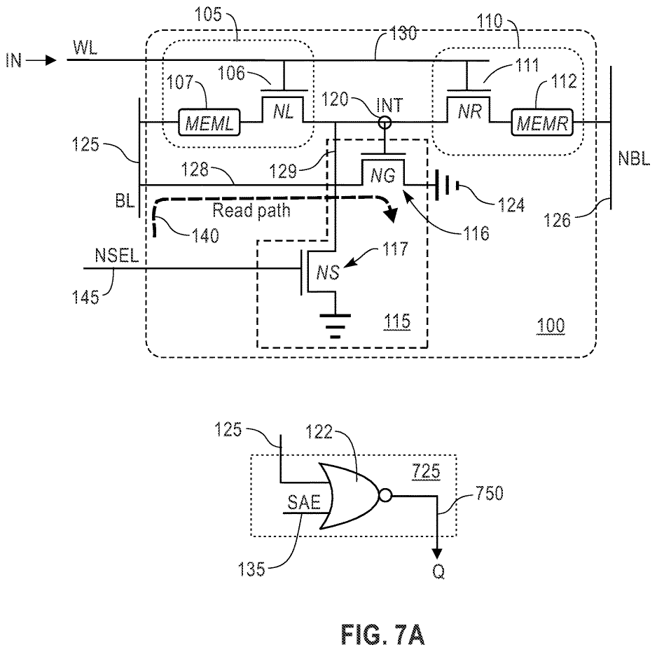

FIG. 7A shows the resistive voltage-divider-based (1b) unit cell 100 of FIG. 1B employed as a memory cell to store one bit (1b) and FIG. 7B shows multiple resistive voltage-divider-based (1b) unit cells 100 configurable as a memory structure for storing weight matrix array values for DIMC or AIMC operations in an in-memory computing system. The resistive voltage-divider-based (1b) unit cell 100 of FIG. 7A includes a read bit line conductor 125 (e.g., TRUE BL) that connects to a readout sense amplifier 725 (e.g., a voltage threshold detector) configured with the NOR/NAND gate 122 in the embodiment depicted that is enabled by an ENABLE signal 135 and which provides a binary output bit Q 750.

FIG. 7B shows a W (weight) matrix memory structure 700 storing weight values in a two-dimensional (2D) array of resistive voltage-divider-based (1b) unit cells 100 of FIG. 7A. Generally, the W weight matrix structure 700 shown in FIG. 7B is an n×m matrix having n rows 702₀, 702₁, . . . , 702ₙ and m columns 704₀, 704₁, . . . , 704ₘ per row with a resistive voltage-divider-based (1b) unit cell 100 connected at each intersection. As shown in FIG. 7B, each resistive voltage-divider-based (1b) unit cell 100 along a column is connected to both a single read bit line conductor 125 (e.g., TRUE BL or BL) as shown in FIG. 7A and a single complementary read bit line 126 (e.g., COMP BL or NBL), e.g., BL<0> and corresponding NBL<0> connecting resistive voltage-divider-based (1b) unit cell 100 along column 704₀, BL<1>and NBL<1> connecting resistive voltage-divider-based (1b) unit cells 100 along column 704₁, . . . , BL<m> and NBL<m> connecting resistive voltage-divider-based (1b) unit cells 100 along column 704ₘ. As further shown in FIG. 7B, each resistive voltage-divider-based (1b) unit cell 100 along a row is connected to both a single wordline (WL) conductor 130 (WL) as shown in FIG. 7A and the read or write enable conductor line 145 (alternately referred to as NSEL), e.g., WL<k> and NSEL<k> connecting resistive voltage-divider-based (1b) unit cells 100 along row 702₁, WL<k+1> and NSE<k+1> connecting resistive voltage-divider-based (1b) unit cells 100 along row 702₁, and WL<n> and NSEL<n> connecting resistive voltage-divider-based (1b) unit cells 100 along row 702ₙ. The resistor devices 107, 112 of the unit cells themselves can be of any NVM technology that stores data as resistance values, e.g., RRAM, PCM, FeRAM, STT-MRAM and the like.

Further configured at each respective column of the W weight matrix structure 700 is a respective sense amplifier (SA) 725 which can sense the results of a read operation at each node(s) along the respective individual column 704₀, 704₁, . . . , 704ₘ. For example, the TRUE bitline BL<0> connected to resistive voltage-divider-based (1b) unit cells 100 along a column 704₀ connects to single sense amplifier (SA) 725 which can include the NOR/NAND gate 122 enabled by sense amplifier ENABLE signal 135. Sense amplifier 725 at column 704₀ can read the TRUE bitline BL<0> value, e.g., after an MVM operation, and provide a corresponding output result providing an output bit Q<0>. Likewise, sense amplifier 725 at column 704₁ can read the TRUE bitline BL<1> value and provide a corresponding output result providing an output bit Q<1>, and sense amplifier 725 at column 704ₘ can read the TRUE bitline BL<m> value and provide a corresponding output result providing an output bit Q<m>.

To read a result output bit at the resistive voltage-divider-based (1b) unit cells 100 along a row using the resistive divider, the following steps are performed to initialize the resistive voltage-divider-based unit cell 100 including: applying a value NSEL=0 to read or write enable conductor line 145, applying a value WL=1 to WL conductor 130 functioning as a select line, applying and disconnecting a voltage value, e.g., TRUE BL=VDD (floating) at to read bit line conductor 125, and applying a value, e.g., ground or NBL=0 (floating) at complementary read bit line 126. With these values, a voltage divider circuit is developed between MEML+NL and MEMR+NR for each unit-cell. The internal node voltage V_{INT} voltage is developed at INT node 120, and the value at read bit line is discharged through gate-controlled transistor (NG) 116 for a pre-determined time duration.

In FIG. 7B, at the NOR-based sense amplifier 725, there is applied an ENABLE signal 135 at an SAE signal line to perform NOR-based sensing. After SAE is enabled, the wordline conductor 130 is reset back to WL=0 and the read or write enable conductor line 145 is reset to NSEL=1 (to reset INT node 120). The TRUE BL and COMP BL (NBL) are pre-charged and pre-discharged to VDD and VSS, respectively.

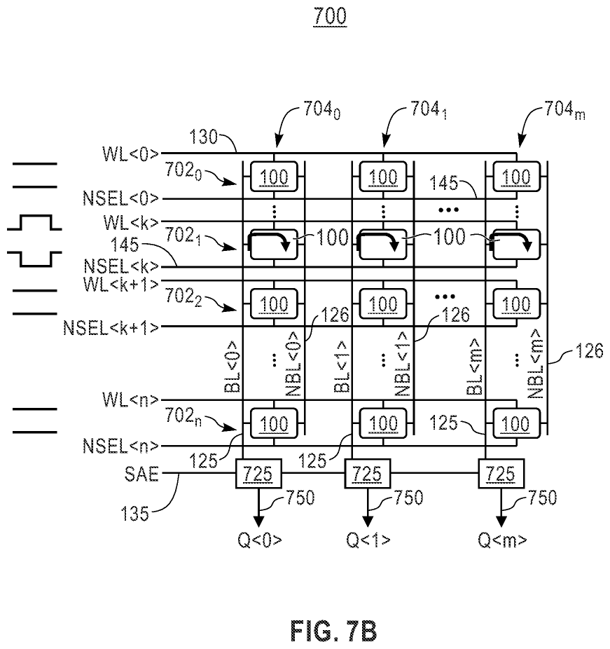

The embodiments depicted in FIGS. 1A, 1B and 2 can be implemented in NMOS device technology or PMOS device technology. FIG. 8 depicts a variation of the resistive voltage-divider-based (1b) unit cell 100 of FIG. 1B to accommodate a PMOS-based transistor device technology and use of NAND gate sensing device. In this embodiment, the voltage-divider-based resistor unit cell 800 differs by replacing the NMOS gate-controlled transistor (NG) 116 with a PMOS gate-controlled transistor (PG) device 816 and similarly, replacing further NMOS FET transistor device 117 with a PMOS transistor device 817. As a consequence, the drain or source terminal of gate-controlled transistor (PG) device 816 is connected to a VDD supply source 824 rather than a ground and similarly, the drain or source terminal of (PS) transistor device 817 is connected to the VDD supply. Further, rather than a NOR sensing gate, the read bit line conductor 125 is connected to a NAND gate 822 for sensing the toggling at the read bit line conductor 125 to generate a binary output 850. In the embodiment of the resistive voltage-divider-based unit cell 800 implementing PMOS technology of FIG. 8, the INT node INT 120 is connected to the gate of a gate-controlled (PG) transistor 826, i.e., a pull-up transistor, and the voltage at INT node 120 is now initialized to the VDD voltage. Further, the initialization pre-charging at the (BL) read bit line conductor 125 and comp read bit line (NBL) 126 is reversed: BL is pre-discharged to VSS and NBL is pre-charged to VDD voltage. As further shown in FIG. 8, the voltage detecting sensing circuit 801 for sensing the toggling of the voltage at the read bit line conductor 125 is a NAND gate 822 (instead of a NOR gate) to sense if the unit cell allows a high voltage at the BL (e.g., read 1) after the readout or it remains at low voltage (e.g., read 0). The enable signal (SAE signal) 835 is an active low for the NAND gate 822. Further, in the embodiment depicted in FIG. 8, the power supply for the PMOS is required to initialize INT node 820 to VDD for writing a bit value to the unit cell.

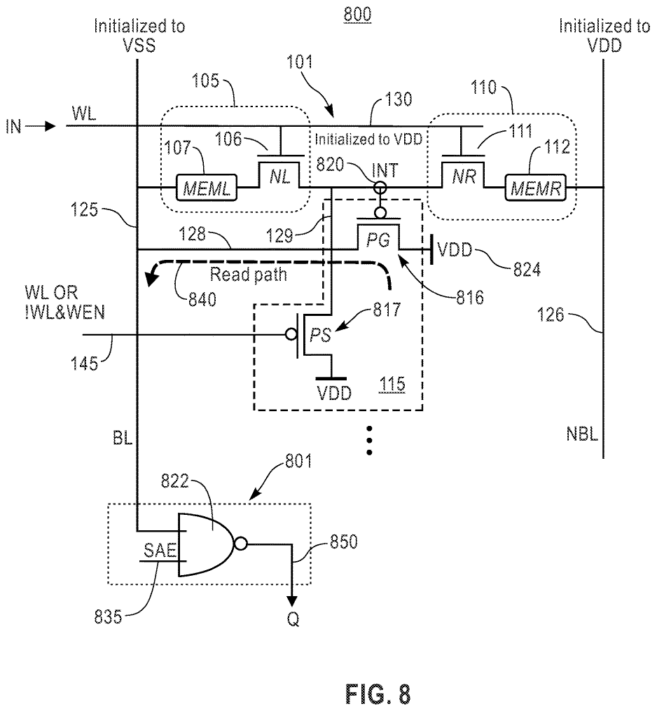

FIG. 9 depicts a three-dimensional (3D) NAND-flash NVM architecture 900 incorporating the resistive voltage-divider-based unit cell structure of FIG. 1B. In the 3D NAND-flash NVM architecture 900, there is organized a plurality of memory tile planes 902, each memory tile plane 902 having two adjacent blocks or columns 904A, 904B, with first column having an array of daisy-chained connection of transistors 905A (connected drain to source) each for storing “true” data bits and corresponding second column having an array of daisy-chained connection of transistors 905B (connected drain to source) storing respective complementary or “comp” data bits. Each of the connected “true” bit transistors 905A of column 904A and “comp” bit transistors 905B of column 904B have a respective gate terminal connected to an individual addressable wordline 930 (WLT and WLC, respectively) to select a particular bit memory cell row or tier 906. Each row of transistors 905A, 905B of the memory tile planes 902 forms a memory page 908 that share the same word line 930. Each of the two adjacent columns 904A, 904B for storing true and complementary data on two adjacent transistors 905A, 905B are organized as a number of tiers 906 of flash memory cells connected to a readout circuit 950 that provides a respective output bit Q<n>, where n=0, 1, . . . , m. At a respective memory tile plane 902, connection to the top transistor of column 904A is a power supply source, e.g., VDD, and a connection to the top transistor of column 904B is a ground or VSS supply. At the bottom of the daisy-chained connection of transistors 905A, 905B is the readout circuit 905 including a connected voltage-divider-based resistive unit cell 901 configuration according to the embodiments described herein. In particular, the drain (or source) terminal of the bottom transistor 905A of column 904A and the drain (or source) terminal of the bottom transistor 905B of column 904B are connected together and define a common single node or INT node 920. In the readout circuit 950, the INT node 920 connects to a gate terminal of a gate-controlled transistor device 916, which device, as in the case of the other embodiments, has one terminal connecting a read bit line 925 and another terminal connecting to ground 924. Further the read bit line 925 is one input to an output voltage threshold detector 922, e.g., a NOR gate, providing a binary output Q<*> of each tile 902 of the memory tile plane of a page 908. In accordance with the embodiments herein, the INT node 920 controls gate-controlled transistor device 916 to form an output read path 940 which toggles the voltage at the bit line 925 that is sensed by output voltage threshold detector 922 and used to determine a binary output.

Thus, the 3D NAND-flash NVM 900 of FIG. 9 stores true and complementary data on two adjacent NAND transistor devices 905A, 905B on the two adjacent columns 904A, 904B.

For a 3D NAND memory readout, the two columns 904A, 904B have a common access line forming INT node 920 that acts as the internal node. In the periphery, the read bit line (BL) 925 can be common to other pages of NAND tiles 902. In an embodiment, the source on the TRUE source line is initialized to the VDD supply rail and the source of the COMP source line is initialized to VSS. For the unselected one pages, both source lines are at VSS to initialize INT node 920 to a value at VSS. A single-cycle readout can be done of all the columns within the page of the NAND tile, denoted by Q<*>.

The programming or writing of a bit value to the 3D NAND-flash memory architecture 900 incorporating the resistive voltage-divider-based unit cell structure 901, involves connecting the respective true and comp transistor devices 905A, 905B with dedicated wordlines (WLs) 930 (WLT and WLC). Thus, to write to a TRUE device, WLT is set to the required voltage and rest of the devices, along with COMP device, can be high conducting. The read bit line (BL) 925 can be initialized to high write voltage (e.g., VDD) and NBL can be initialized at VSS to allow the voltage-divider-based resistor unit cell to function.

In terms of incorporation of the 3D NAND-flash memory architecture 900 incorporating the resistive voltage-divider-based unit cell structure 901, an array includes the number of pages 908 and the number of memory tile planes 902 (or columns) in a page have no particular restriction (length along the BL and length of ‘m’, respectively). Further, the number tiers 906 can be adjusted to target the speed of the readout. That is the read bit line (BL) 925 is connected to each all the pages 908.

The 3D NAND-flash memory 900 embodiment of FIG. 9 can be modified to accommodate PMOS-based technique i.e., pull-up devices with the GATE connection to INT and initialization of this node to VDD. Also in this embodiment, the read bit line 925 (BL) is initialized to VSS and NBL to VDD. The remainder of the source lines (e.g., unselected columns/tiers) are connected to VDD. In this embodiment, the output voltage threshold detector 922 can be replaced with a NAND gate sensing device (rather than NOR gate device) for providing a binary output Q<*> of each tile 902 of the memory tile plane of a page 908.

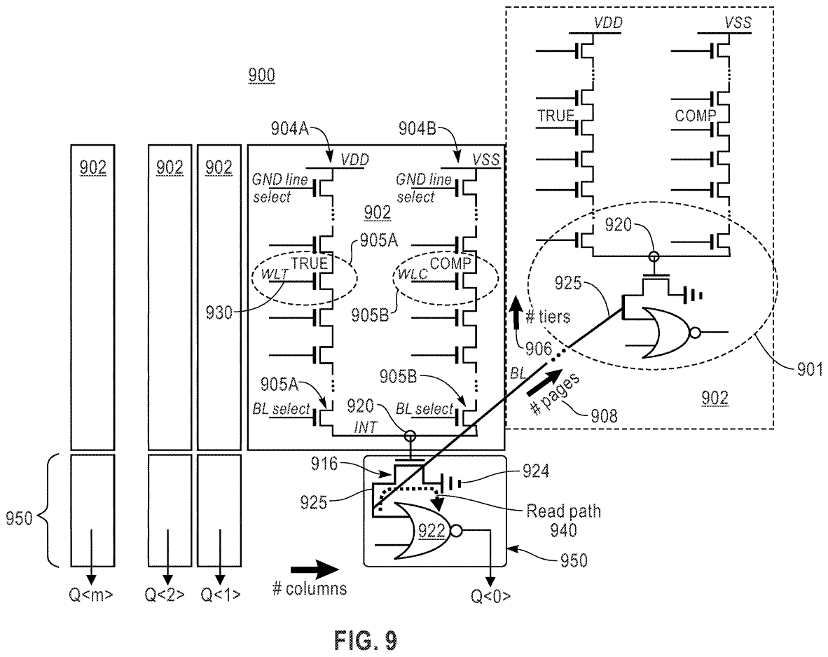

FIG. 10 depicts a three-dimensional (3D) NOR-flash NVM architecture 1000 incorporating the resistive voltage-divider-based unit cell structure of FIG. 1B. In the 3D NOR-flash NVM architecture 1000, there is organized a plurality of memory tile planes 1002, each memory tile plane 1002 having one or more columns, with each column 1004 forming an array of pairs of parallel connected transistors 1005A, 1005B for storing a respective “true” data bit and corresponding complementary or “comp” data bit. Each of the parallel-connected pair of “true” bit transistors 1005A and “comp” bit transistors 1005B of a column 1004 have a respective gate terminal connected to an individual addressable wordline 1030 (WLT and WLC, respectively) to select/access a particular (true or comp) bit memory cell row or tier 1006. A respective same row or tier of parallel-connected transistors 1005A, 1005B of the memory tile planes 1002 forms a memory page 1008 accessible by a same word line 1030. Further, connected at the bottom of each tile is an output read circuit 1050 that output a respective selected bit. The page outputs are organized according to Q #tier<#column>, e.g., Q0<n>, Q1<n>, Q 2<n>, etc., where n=0, 1, . . . , m.

Further, at each of the parallel-connected pair of “true” bit transistors 1005A and “comp” bit transistors 1005B of a column 1004 is a connected voltage-divider-based resistive unit cell 1001 configuration according to the embodiments described herein. In particular, the drain (or source) terminal of the parallel-connected transistor 1005A of column 1004 and the source (or drain) terminal of the bottom transistor 1005B of column 1004 are connected together and define a common single node or INT node 1020. In an embodiment, the INT node 1020 connects to a gate terminal of a gate-controlled transistor device 1016, which device, as in the case of the other embodiments, has one terminal connecting a read bit line 1025 and another terminal connecting to ground. Further the read bit line (BL) 1025 is one input to an output voltage threshold detector gate device 1022, e.g., a NOR gate, providing a binary output Q<*> of each memory tile plane 1002 of a page 1008.

Connected to the bottommost transistor of the column 1004 of the memory tile plane 1002 is a readout circuit 1050 that provides a respective output bit, e.g., Q #tier<#column>, where #tier=0 and #column=0. The read bit line 1025 is one input to an output voltage threshold detector gate device 1022, e.g., a NOR gate, providing a binary output Q #tier<#column> of each memory tile plane 1002 of a page 1008. In accordance with the embodiments herein, the INT node 1020 controls gate-controlled transistor device 1016 to form an output read path 1040 which toggles the voltage at the bit line 1025 that is sensed by NOR gate voltage threshold detector gate device 1022 and used to determine a binary output.

In terms of incorporation of the 3D NOR-flash NVM architecture 1000 incorporating the voltage-divider-based resistive unit cell 1001, where true and complementary data are stored on two adjacent NOR devices (transistors 1005A, 1005B, the two devices has a common internal INT node 1020, the read bit line 1025 (BL) is initialized to VDD and 1026 (NBL) is initialized to VSS to enable the voltage-divider-based resistor unit cell to generate an output. Since the connection to BL and NBL is alternate, an embodiment can program in mixed alternate fashion i.e., TRUE0: COMP0: COMP1: TRUE1: COMP2: COMP3, etc..

Further, for the 3D NOR-flash memory readout operation, a single-cycle tier readout can be performed of all the columns and pages of the memory tile planes 1002, denoted by Q<*> which assumes NOR is available in a separate tier for an entire page without time-multiplexing.

For programming or writing true or comp values to the 3D NOR-flash NVM architecture 1000, the true and comp. transistors 1005A, 1005B are connected to dedicated WLs 1030 (WLT and WLC). For instance, to write TRUE device, WLT is set to the required voltage and rest of the devices, along with COMP device, can be high conducting. The true read bit line 1025 (BL) can be high write voltage and comp bit line 1026 (NBL) can be at VSS.

The 3D NOR-flash NVM architecture 1000 can thus be configured as an array including the number of tiers, number of pages 1008 and the number of columns or memory tile planes 1002 in a page have no particular restriction.

The 3D NOR-flash NVM architecture 1000 embodiment of FIG. 10 can be modified to accommodate PMOS-based technique i.e., pull-up devices with the GATE connection to INT and initialization of this node to VDD. Also in this embodiment, the read bit line 1025 (BL) is initialized to VSS and NBL to VDD. The remainder of the source lines (e.g., unselected columns/tiers) are connected to VDD. In this embodiment, the output voltage threshold detector gate device 1022 can be replaced with a NAND gate sensing device (rather than NOR gate device) for providing a binary output Q<*> of each tile 1002 of the memory tile plane of a page 1008.

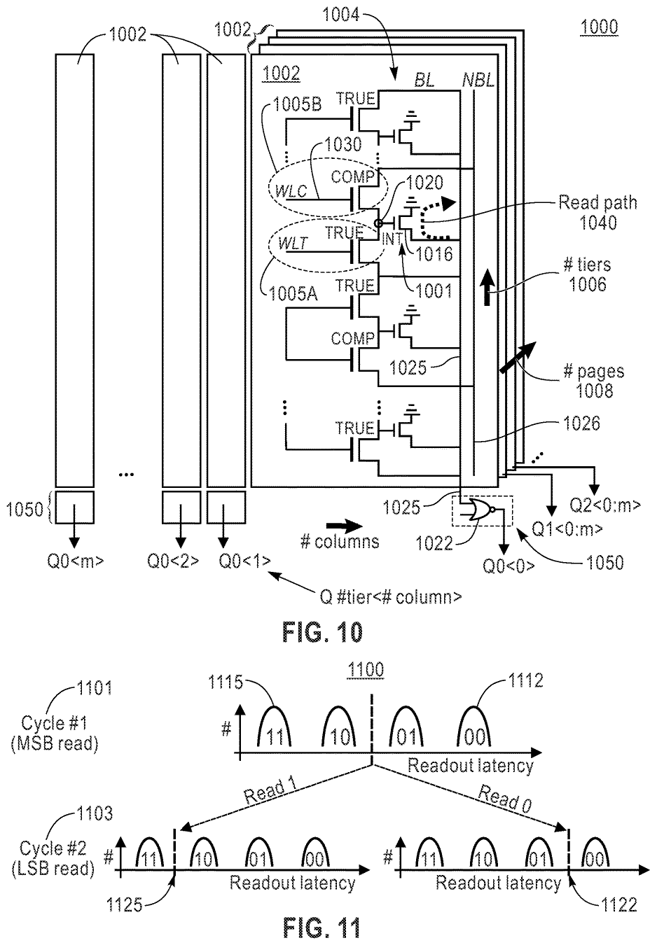

FIG. 11 depicts a further result of a voltage-divider-based NVM device configured for multi-level storage and readout, for example, according to the embodiments herein. This multi-level output result can be obtained by programming (writing) different conductance ratios on the two complementary resistive devices (e.g., MEML, MEMR). Possible two-bit (2b) states could have the following conductance ratio (CR) with:
State→res(TRUE)|res(COMP)
00→333 kΩ|30 kΩ(CR=1/11 )≈8 ns
01→250 kΩ|40 kΩ(CR=1/6 )≈5 ns
10→125 kΩ|80 kΩ(CR=2/3 )≈2 ns
11→250 kΩ|40 kΩ(CR=2 )≈0.35 ns

Where res(TRUE) is a programmed resistance value, e.g., of the MEML resistor, and res(COMP) is a programmed resistance value, e.g., of the MEMR resistor of the voltage-divider-based resistor unit cell. When used for multi-level storage and readout, the voltage-divider-based resistive unit cell is programmed with the specific ratio of MEML, MEMR resistive values and further requires different SAE device enable pulse widths or modified voltage of operation to produce multi-bit readouts at the readout circuit, e.g., NOR or NAND voltage threshold detector gate. Thus, as shown in the example embodiment of FIG. 1A, different read schemes can employ different timed ENABLE signals 135 that can be used to detect the outputting of specific stored multilevel bits, e.g., which discharge at different times.

In FIG. 11, there is depicted an example plot 1100 showing the number of cycles including a first cycle 1101 for most significant bit (MSB) readout against the resultant readout latency and in a second cycle 1103 for the least significant bit (LSB) readout. For example, each two-bit readout is delayed based on the conductance ration (CR), e.g., with a 2b MSB state 1112 of ‘00’ readout being the most latent (e.g., 8 ns) given its configuration of a small conductance ratio of MEML, MEMR resistive values (e.g., CR=1/11), and the 2b MSB state 1115 of ‘11’ being the least latent (e.g., 0.35 ns) given its configuration of a largest conductance ratio of MEML, MEMR resistive value (e.g., CR=2).

In view of FIG. 11, it is the case that a programmed binary search can be conducted to determine the output of the readout circuit. For example, based on the computed readout latency for the 2b MSB state 1112, a LSB ‘0’ output value can be read out at a readout circuit at the predicted LSB time, e.g., latent time 1122 of about 8 ns known to provide LSB output ‘0’ bit at the output NOR gate; while similarly, based on the computed readout latency for the 2b MSB state 1115, a LSB ‘1’ output value can be read out at a readout circuit at the predicted LSB time, e.g., latent time 1125 of about 0.35 ns known to provide LSB output ‘1’bit.

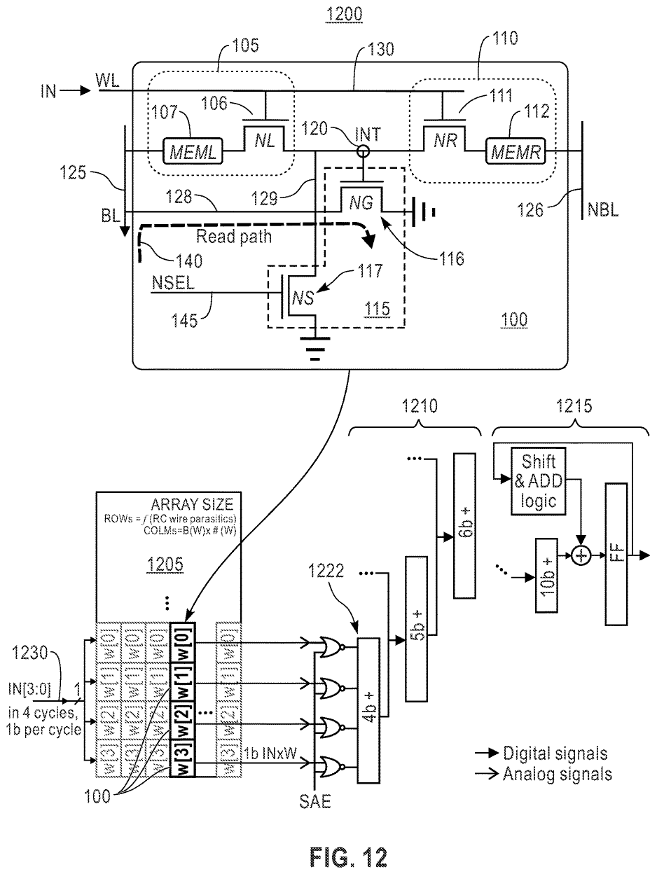

FIG. 12 depicts a further embodiment having a DIMC computing block 1200 using 2D non-volatile memory 1205. As shown in FIG. 12, the MULT (IN×W) output readout, e.g., output of bitwise multi-bit IN and multi-bit W based MVM operations by the fully digital SA-less readout operation at 1222, is followed by digital ADDER tree 1210 and shift-and-add accumulator blocks (readout) 1215 that conclude the MVM.

In an example implementation shown in FIG. 12, the multi-bit W is stored in multiple proposed resistive voltage-divider-based unit cells 100. Here, a 4-bit W (e.g., W[0], W[1], W[2], W[3]) is stored in four resistive voltage-divider-based unit cells 100 with varying bit significance. Each group of bits corresponding to a W receives the IN bit of an IN[3:0] input 1230. One IN bit is received per cycle resulting in a group of partial products. The ADDER tree 1210 aggregates these partial products (binary MULT outputs) to perform sum-of-products or dot-product of the entire selected row, e.g., in shift+accumulate blocks 1215. This is repeated for each IN bit and each time the shift+accumulate block 1215 accommodates for INPUT bit significance of the incoming dot products to complete multi-bit W and multi-bit IN based MVM operation. A final accumulation of results takes one additional cycle.

For an embodiment using 2D NVMs, the NOR gates 1222 can be replaced with NAND gates. Additionally, for 2D NVMs in the embodiment of FIG. 11 involving multi-level cells (MLC), there is performed b(IN)×b(unit-cell)+1 cycles to perform MVM, where b(unit-cell) is the number of bits stored in a single unit-cell. For instance, for a 4-bit IN and 4-bit W with each device storing 2b, it is required that two unit-cells represent a 4-bit W and a requirement of 4×2+1=9 cycles. In contrast, for a single-level (SLC) require four unit-cells to represent 4-bit W and requires 4×1+1=5 cycles. For 3D NVMs in the embodiments described herein, it may require more complicated IN buffering and ADDER TREE circuitry to obtain a suitable solution for DIMC.

In each of the embodiments herein, the main advantages of using resistive voltage-divider-based (1b or multi-bit) unit cells 100 include: 1) Fast readout for large memory arrays with binary storage. This is because the read path is decoupled from the high resistive path of resistive device and only concern with the almost full-ON or OFF transistor device (NG) discharge or not-discharging the BL; 2) The readout is robust against device variations and provides a binary output; 3) The readout does not use an expensive sense-amplifier, instead uses a simple NOR/NAND gate (as a voltage threshold detector) to sense the difference between a read 0 case and a read 1 case; and 4) Is energy efficient in the sense that charge-sharing (between the BL and TRINT gate node) is used in the first phase of the read operation i.e., voltage division, whereas, prior art use constant voltage supply for division.

While the present application has been particularly shown and described with respect to various embodiments thereof, it will be understood by those skilled in the art that the foregoing and other changes in forms and details may be made without departing from the spirit and scope of the present application. It is therefore intended that the present application not be limited to the exact forms and details described and illustrated but fall within the scope of the appended claims.

What is claimed is:

1. A memory device for in-memory computing operations, the memory device comprising:
a resistive unit cell comprising:
a first switching device (NL) and a first resistor connected in series; and a second switching device (NR) and a second resistor connected in series, each first switching device and second switching device having a terminal connected at a single common node to form a voltage divider circuit, the voltage divider circuit storing a bit value in a binary complementary format as a floating charge distributed between the first resistor and second resistor, and the first switching device (NL) and second switching device (NR) activated to provide a voltage at said single common node; and
a gate-controlled switching transistor device (NG) having a control terminal connected to said single common node for receiving said voltage provided at said single common node, said gate-controlled switching device responsive to said voltage provided at said single common node for generating a read path through the gate-controlled switching transistor device to discharge a signal representing said bit value from either said first resistor or second resistor for reading said bit value at a read sensor device.

2. The memory device of claim 1, further comprising:
a bit line conductor connected to the read sensor device, and said bit line conductor further connected to one end of the first resistor, said bit line conductor discharging a floating charge distributed at the first resistor representing said bit value via the generated read path for a pre-determined time duration, said read sensor device reading a change in a voltage at said bit line conductor.

3. The memory device of claim 2, further comprising:
a select wordline conductor connected to a gate control terminal of each said first switching device (NL) and second switching device (NR), said select wordline conductor providing a signal asserted for activating said first switching device (NL) and said second switching device (NR) of said resistive unit cell to control reading of the bit value.

4. The memory device of claim 3, wherein said read path connects said bit line conductor to a ground potential through said gate-controlled switching transistor device, said gate-controlled switching transistor device (NG) configured to receive, at the control terminal, said voltage at said single common node to control a conductance of said generated read path based on the conductance, the conductance effecting a discharge speed of said floating charge distributed to the first resistor and second resistor via said read path.

5. The memory device of claim 1, wherein said read sensor device is a voltage threshold detector for detecting either a logic 1 or logic 0 bit value, said voltage threshold detector for detecting either a logic 1 or logic 0 bit value is one of: a NAND gate or a NOR gate.

6. The memory device of claim 1, where the first resistor device and second resistor device can be configured to provide different conductance ratios, wherein the first resistor device and second resistor device are configurable to provide a conductance ratio sufficient for storing a 2-bit state on the first resistor and second resistor, said read sensor device being timed to provide a multi-bit readout.

7. The memory device of claim 4, further comprising:
a further switching transistor (NS) having a control terminal for receiving a write enable signal, a first terminal connected to said single common node and a second terminal connected to a ground potential, said write enable signal enabling a writing of a voltage representing said bit value for distribution as a floating charge stored at said first resistor or second resistor.

8. A method for operating a memory device, the method comprising:
storing a weight value in a resistive unit cell, the resistive unit cell comprising:
a first switching device (NL) and a first resistor connected in series; and a second switching device (NR) and a second resistor connected in series, each first switching device and second switching device having a terminal connected at a single common node to form a voltage divider circuit, the voltage divider circuit storing a bit value in a binary complementary format as a floating charge distributed between the first resistor and second resistor, and the first switching device (NL) and second switching device (NR) activated to provide a voltage at said single common node; and
a gate-controlled switching transistor device (NG) having a control terminal connected to said single common node for receiving said voltage provided at said single common node; and
generating a read path through the gate-controlled switching transistor device to discharge a signal representing said bit value from either said first resistor or second resistor for reading said bit value at a read sensor device.

9. The method of claim 8, wherein the memory device further comprises: a bit line conductor connected to the read sensor device, and said bit line conductor further connected to one end of the first resistor, said method further comprising:
discharging, via said bit line conductor, a floating charge distributed at the first resistor representing said bit value via the generated read path for a pre-determined time duration; and
reading, by said read sensor device, a change in a voltage at said bit line conductor.

10. The method of claim 9, where said memory device further comprises: a select wordline conductor connected to a gate control terminal of each said first switching device (NL) and second switching device (NR), said method further comprising:
providing, to said select wordline conductor, a signal asserted for activating said first switching device (NL) and said second switching device (NR) of said resistive unit cell to control a reading of the bit value by said read sensor connected to said bit line conductor.

11. The method of claim 10, wherein said read path connects said bit line conductor to a ground potential through said gate-controlled switching transistor device, said method further comprising:
receiving, at the control terminal of said gate-controlled switching transistor device (NG), said voltage at said single common node to control a conductance of said generated read path based on the conductance, the conductance effecting a discharge speed of said floating charge distributed to the first resistor and second resistor via said read path.

12. The method of claim 8, wherein said read sensor device is a voltage threshold detector for detecting either a logic 1 or logic 0 bit value.

13. The method of claim 9, wherein said bit line conductor has a corresponding capacitance, said method further comprising:
applying a power supply voltage to the bit line conductor for pre-charging the bit line conductor to a first power supply voltage value as a charge at the corresponding capacitance at said bit line conductor.

14. The method of claim 9, further comprising:
inputting multiple bits of a multi-bit vector for multiplying to a stored bit value in a time multiplex manner, wherein said resistive unit cell multiplies a respective said input bit of said multi-bit vector said vector to the bit value stored at said resistive unit cell; and
adding and accumulating results of each said multiplying of a respective said input bit of said multi-bit vector to the bit value stored at the resistive unit cell.

15. An in-memory computing system comprising:
a plurality of bit line conductors organized as columns of an array;
a plurality of wordline conductors organized as rows of the array;
an array of resistive unit cells along a respective row, each respective resistive unit cell of the array associated with a respective bit line conductor of a respective column and each resistive unit cell of the array associated a single wordline conductor of a single row for activating each of the resistive unit cells along the row of the array, each resistive unit cell comprising:
a first switching device (NL) and a first resistor connected in series; and a second switching device (NR) and a second resistor connected in series, each first switching device and second switching device having a terminal connected at a single common node to form a voltage divider circuit, the voltage divider circuit storing a bit value in a binary complementary format as a floating charge distributed between the first resistor and second resistor, and the first switching device (NL) and second switching device (NR) activated to provide a voltage at said single common node; and
a gate-controlled switching transistor device (NG) having a control terminal connected to said single common node for receiving said voltage provided at said single common node, said gate-controlled switching device responsive to said voltage provided at said single common node for generating a read path through the gate-controlled switching transistor device to discharge a signal representing said bit value from either said first resistor or second resistor for reading said bit value at a read sensor device associated with said respective bit line conductor of the respective column,
wherein each respective read sensor of multiple resistive unit cells along the single row simultaneously read a bit value from the respective resistive unit cell of the single row.

16. The in-memory computing system of claim 15, wherein each bit line conductor of said plurality of bit line conductors is connected to a respective read sensor device, and each said bit line conductor further connected to one end of the first resistor of a respective resistive unit cell, said bit line conductor discharging a floating charge distributed at the first resistor representing said bit value via the generated read path for a pre-determined time duration, said read sensor device of each bit line conductor reading a change in a voltage at each respective bit line conductor.

17. The in-memory computing system of claim 16, wherein the single wordline conductor of a row is connected to a gate control terminal of each said first switching device (NL) and second switching device (NR) of each respective resistive unit cell device in the row, said single wordline conductor providing a signal asserted for activating said first switching device (NL) and said second switching device (NR) of each said resistive unit cell of the row to control reading of the bit value at the respective resistive unit cell.

18. The in-memory computing system of claim 17, wherein said read path of a respective resistive unit cell connects a respective bit line conductor to a ground potential through said gate-controlled switching transistor device, said gate-controlled switching transistor device (NG) of each respective unit cell configured to receive, at the control terminal, said voltage at said single common node to control a conductance of said generated read path of the respective resistive unit cell based on the conductance, the conductance effecting a discharge speed of said floating charge distributed to the first resistor and second resistor via said read path of the respective unit cell.

19. The in-memory computing system of claim 15, wherein said read sensor device connected to a respective bit line conductor of a respective resistive unit cell along a row is a voltage threshold detector for detecting either a logic 1 or logic 0 bit value, said voltage threshold detector for detecting either a logic 1 or logic 0 bit value is one of: a NAND gate or a NOR gate.

20. The in-memory computing system of claim 19, further comprising, at each respective resistive unit cell:
a further switching transistor (NS) having a control terminal for receiving a write enable signal, a first terminal connected to said single common node and a second terminal connected to a ground potential, said write enable signal enabling a writing of a voltage representing said bit value for distribution as a floating charge stored at said first resistor or second resistor of the respective resistive unit cell.

21. The in-memory computing system of claim 18, further comprising:
an adder tree network receiving respective stored bit values read from the respective resistive unit cells of the single row and adding combination of said read bit values; and
shift and accumulation circuits used for processing the respective stored bit values read from the respective resistive unit cells of the single row.

22. A method for performing an in-memory computing operation, said method comprising:
storing a weight value in a complementary binary format in multiple resistive unit cells, each said resistive unit cell comprising:
a first switching device (NL) and a first resistor connected in series; and a second switching device (NR) and a second resistor connected in series, each first switching device and second switching device having a terminal connected at a single common node to form a voltage divider circuit, the voltage divider circuit storing a bit of said weight value in a binary complementary format as a floating charge distributed between the first resistor and second resistor, and the first switching device (NL) and second switching device (NR) activated to provide a voltage at said single common node; and
a gate-controlled switching transistor device (NG) having a control terminal connected to said single common node for receiving said voltage provided at said single common node;
receiving an input operand at a select wordline conductor connected to a gate control terminal of each said first switching device (NL) and second switching device (NR) of each multiple resistive unit cell, said input operand representing a signal to be multiplied by the stored weight value, said input operand activating said first switching device (NL) and said second switching device (NR) of each said multiple resistive unit cell to control a multiplication operation of the stored weight value and said input operand at the multiple resistive unit cells.

23. The method as claimed in claim 22, further comprising:
reading a multiplication operation result of said stored weight value and input operand, said reading comprising:
generating a read path through the gate-controlled switching transistor device in response to said voltage provided at said single common node to discharge a signal representing said multiplication operation result from either said first resistor or second resistor for reading said multiplication operation result at a read sensor device.

24. The method as claimed in claim 22, wherein said input operand is a multi-bit word, a respective one bit of said multi-bit operand being received at the gate control terminal per a processor cycle, a respective multiplication operation of said stored weight value with each respective bit of said multi-bit word occurring over respective multiple processor cycles, the method comprising:
generating, responsive to a multiplication operation occurring at each processor cycle, a partial product result; and
aggregating, using an adder tree circuit, each of the partial product results after each processor cycle.

25. A memory device for in-memory computing operations, the memory device comprising:
a resistive unit cell comprising:
a first switching device (NL) and a first resistor connected in series; and a second switching device (NR) and a second resistor connected in series, each first switching device and second switching device having a terminal connected at a single common node to form a voltage divider circuit, the voltage divider circuit storing a multi-bit value in a binary complementary format as a floating charge distributed between the first resistor and second resistor, and the first switching device (NL) and second switching device (NR) activated to provide a voltage at said single common node; and
a gate-controlled switching transistor device (NG) having a control terminal connected to said single common node for receiving said voltage provided at said single common node, said gate-controlled switching device responsive to said voltage provided at said single common node for generating a read path through the gate-controlled switching transistor device to discharge a signal representing said multi-bit value from either said first resistor or second resistor for reading said multi-bit value at a read sensor device, the multi-bit value determined based on a conductance ratio of said first resistor and said second resistor.
